(19) United States
(12) Patent Application Publication
(10) Pub. No.: US 2025/0294676 A1
(43) Pub. Date: Sep. 18, 2025

(54) MULTILAYER BOARD AND ELECTRONIC DEVICE

(71) Applicant: Murata Manufacturing Co., Ltd., Nagaokakyo-shi, (JP)

(72) Inventors: Akiyoshi MYOGADANI, Nagaokakyo-shi, (JP); Shintaro HIRANO, Nagaokakyo-shi, (JP); Takahiro MINATOYA, Nagaokakyo-shi, (JP); Koushi OKUYAMA, Nagaokakyo-shi, (JP)

(73) Assignee: Murata Manufacturing Co., Ltd., Nagaokakyo-shi, (JP)

(21) Appl. No.: 19/071,792

(22) Filed: Mar. 6, 2025

(30) Foreign Application Priority Data
Mar. 13, 2024 (JP) 2024-038636

(51) Int. Cl. H05K 1/03; H05K 1/02

(52) U.S. Cl. CPC H05K 1/0353; H05K 1/0243; H05K 2201/0141; H05K 2201/10098

(57) ABSTRACT

A multilayer board includes a first board portion, a second board portion, and a raised portion. The first board portion is composed of a first material. The second board portion is composed of a second material, is joined to the first board portion, and includes a protruding portion protruding from the first board portion. The raised portion is composed of the first material, is joined to a base portion of the protruding portion of the second board portion, is raised around the base portion of the protruding portion, and covers part of a side portion of the protruding portion.

### CROSS-REFERENCE TO RELATED APPLICATION

This application claims priority to Japanese Patent Application No. JP 2024-038636 filed on Mar. 13, 2024. The entire contents of the above-identified applications, including the specifications, drawings and claims, are incorporated herein by reference in their entirety.

### BACKGROUND OF THE DISCLOSURE

### 1. Field of the Disclosure

The present disclosure relates to a multilayer board and an electronic device including the multilayer board.

### 2. Description of the Related Art

Japanese Unexamined Patent Application Publication No. 2005-236873 (Patent Document 1) describes a multilayer board including a plurality of insulator layers. Patent Document 1 also describes a multilayer board partially including a region the thickness of which in the lamination direction differs from those of the other portions due to the difference in the number of laminated insulator layers.

### SUMMARY OF THE DISCLOSURE

With a structure partially including a region the thickness of which in the lamination direction differs from those of the other portions due to the difference in the number of laminated insulator layers with conductor layers, a thick portion can be provided with a specified electronic-component-like function. However, assuming stress is concentrated at a portion where the number of laminated insulator layers changes, cracks and chips are more likely to occur.

A feature of the present disclosure is to provide a multilayer board in which cracks and chips are less likely to occur at a portion where the number of laminated insulator layers changes and to provide an electronic device including the multilayer board.
(1) A multilayer board as an example of the present disclosure includes:
   a first board portion that includes laminated resin layers each composed of a first material;
   a second board portion that includes laminated resin layers each composed of a second material, is joined to the first board portion, and includes a protruding portion protruding from the first board portion; and
   a raised portion composed of the first material, joined to a base portion of the protruding portion of the second board portion, raised around the base portion of the protruding portion, and covering part of a side portion of the protruding portion, and
   a bottom portion of the second board portion, the bottom portion being part of a joint surface of the second board portion with the first board portion, is located below an upper surface of the first board portion.
(2) An electronic device as an example of the present disclosure includes the multilayer board and an electronic component mounted on the multilayer board.

The present disclosure provides a multilayer board in which cracks and chips are less likely to occur at a portion where the number of laminated insulator layers changes and also provides an electronic device including the multilayer board.

### BRIEF DESCRIPTION OF THE DRAWINGS

FIG. 1 includes sectional views of a multilayer board 101 according to a first embodiment;

FIG. 2 is a diagram illustrating, in particular, the shape of a raised portion 3;

FIG. 3 is a diagram illustrating the positional relationship between a first board portion 1 and a second board portion 2;

FIG. 4 is a diagram illustrating the shape of a joint portion between the first board portion 1 and a base portion of the second board portion 2;

FIG. 5 includes sectional views of the multilayer board 101 during manufacturing;

FIG. 6 includes sectional views of another multilayer board 101A according to the first embodiment;

FIG. 7 is a sectional view of a multilayer board 102 according to a second embodiment;

FIG. 8 is a plan view of the multilayer board 102;

FIG. 9 is a sectional view of a multilayer board 103 according to a third embodiment; and

FIG. 10 is a sectional view of an electronic device 301 according to a fourth embodiment.

### DESCRIPTION OF THE PREFERRED EMBODIMENTS

Hereinafter, embodiments in which the present disclosure is implemented will be described by using several specific examples with reference to figures. In the figures, the same portions are denoted by the same symbols. In consideration of making explanation and understanding of the gist easier, the embodiments will be described by being separated into a plurality of embodiments for convenience of explanation. However, the configurations described in different embodiments may be partially omitted, replaced, or combined. In the second and subsequent embodiments, description of the items common to those in the first embodiment will be omitted, and only different points will be described. In particular, the same or similar effects and advantages by the same or similar configurations will not be referred to in every embodiment.

### First Embodiment

The first embodiment describes, as an example, a multilayer board including a first board portion, a second board portion, and a raised portion.

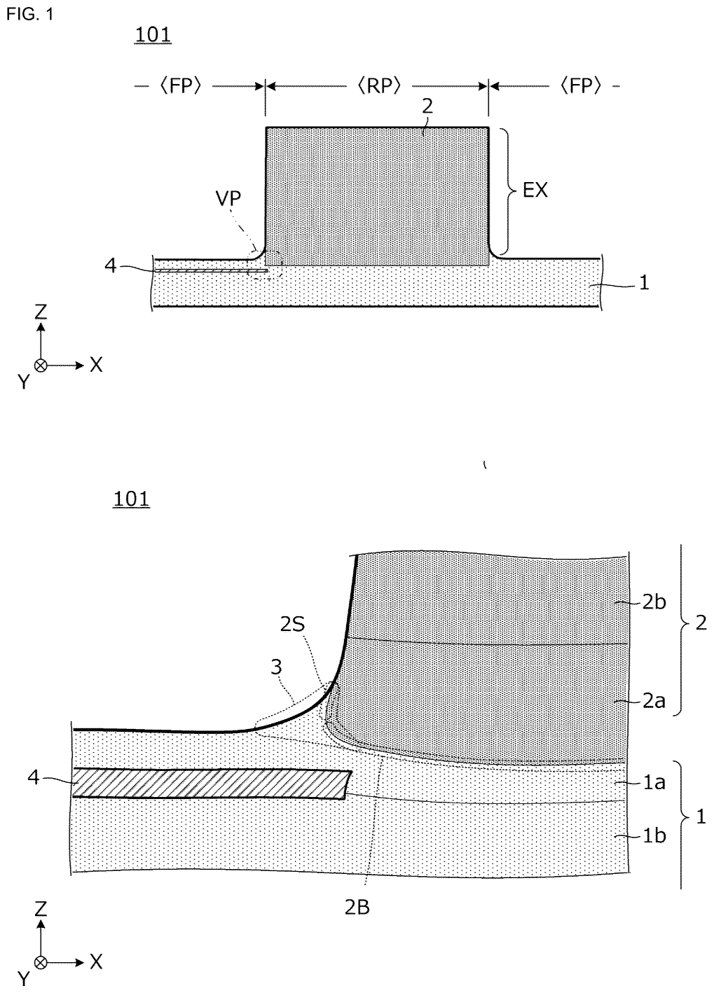

FIG. 1 includes sectional views of a multilayer board 101 according to the first embodiment. In FIG. 1, an upper diagram illustrates a sectional view of part of the multilayer board 101, and a lower diagram illustrates an enlarged view of a VP region in the upper diagram. Note that in a sectional view, lines appearing in the cross section (lines that appear by cutting) are depicted, and illustration of lines present behind the cross section is omitted. This also applies to every embodiment described later.

As illustrated in the upper diagram in FIG. 1, the multilayer board 101 includes a first board portion 1 and a second board portion 2 including a protruding portion EX protruding from the first board portion 1. When expressed in a plane parallel to an X-Y plane, a portion where the second board portion 2 is present is a rigid portion RP where the rigidity is high because a large number of resin layers are laminated to compose the multilayer board, and a portion where the second board portion 2 is not present is a flexible portion FP.

The statement that the second board portion 2 includes the protruding portion EX joined to the first board portion 1 and protruding from the first board portion 1 can also be expressed as the second board portion 2 composing the protruding portion EX.

The first board portion 1 and the second board portion 2 include specified necessary conductor layers laminated together with the resin layers. FIG. 1 includes a conductor layer 4 formed by patterning a Cu foil.

The first board portion 1 is composed of a first material, and the second board portion 2 is composed of a second material. In FIG. 1, the first board portion 1 and the second board portion 2 are hatched differently.

The first material has a lower Young's modulus than the second material. This enables the deformation of the rigid portion RP to be less and the flexible portion FP to be bent.

Young's modulus can be determined by performing a nanoindentation test according to JIS Z 2255 or ISO 14577. For example, Young's modulus can be determined from load-displacement data obtained by using a Micro Nanoindenter available from KLA Corporation.

For example, the first material and the second material are of the same kind. Assuming the first material and the second material are of the same kind as mentioned above, the reliability of connection can be high. For example, both the first material and the second material are liquid crystal polymer resins (LCPs). Use of resin materials with low water absorption such as liquid crystal polymer resins (LCPs) mentioned above enables a multilayer board having high electrical characteristics and high reliability to be obtained.

Whether the same kind of resin materials are used can be checked by using a Fourier-transform infrared spectroscopy instrument (FT-IR). Specifically, the spectra of the second board portion 2 and the first board portion 1 are obtained by using the Fourier-transform infrared spectroscopy instrument (FT-IR). Assuming the spectra of the second board portion 2 and the first board portion 1 have the same peaks, it can be determined that the same kind of resin materials are used.

In the case in which the same kind of resin materials are thermoplastic resins, the difference in the melting point is small. Whether the resin portion of the first board portion 1 and the resin portion of the second board portion 2 are composed of the same kind of resin materials can be checked by observing the endothermic peaks measured by differential scanning calorimetry (DSC). Specifically, by using DSC8230 available from Rigaku Corporation, the temperature of the two resin materials is increased at a rate of 10° C./minute until the two resin materials are melted, then the temperature is decreased, and again the temperature of the two resin materials is increased at the rate of 10° C./minute. Assuming the difference in the melting point between the two resin materials determined in this measurement is 5° C. or less, the two resin materials can be regarded as the same kind of resin materials.

The first board portion 1 illustrated in the upper diagram in FIG. 1 includes resin layers 1a and 1b illustrated in the lower diagram in FIG. 1. The second board portion 2 includes resin layers 2a and 2b.

In the lower diagram in FIG. 1, the first board portion 1 and the second board portion 2 are joined at the boundary plane (the boundary line in FIG. 1 because FIG. 1 includes sectional views) between the portions hatched differently.

As illustrated in the lower diagram in FIG. 1, the multilayer board 101 includes a raised portion 3. The raised portion 3 is joined to part of a base portion 2B of the second board portion 2, is raised around the base portion 2B, and covers part of a side portion 2S of the second board portion 2.

With a structure in which the first material of the first board portion 1 is raised to be joined to part of the base portion 2B of the second board portion 2 and covers part of the side portion 2S of the second board portion 2 by being raised around the base portion 2B of the second board portion 2 as described above, a root portion of the second board portion 2 is held in the main part of the first board portion 1 by the raised portion 3.

In general, assuming an external force is exerted on a multilayer board so as to curve the multilayer board, stress is more likely to concentrate at the boundary between the rigid portion RP and the flexible portion FP (where the number of laminated resin layers significantly changes). Since the joining strength between the first board portion 1 and the second board portion 2 is high in the multilayer board 101 of the present embodiment, cracks and chips can be prevented at the interface between the first board portion 1 and the second board portion 2. Since the second board portion 2 has a higher rigidity than the first board portion 1, the deformation of the second board portion 2 such as inclination can be reduced.

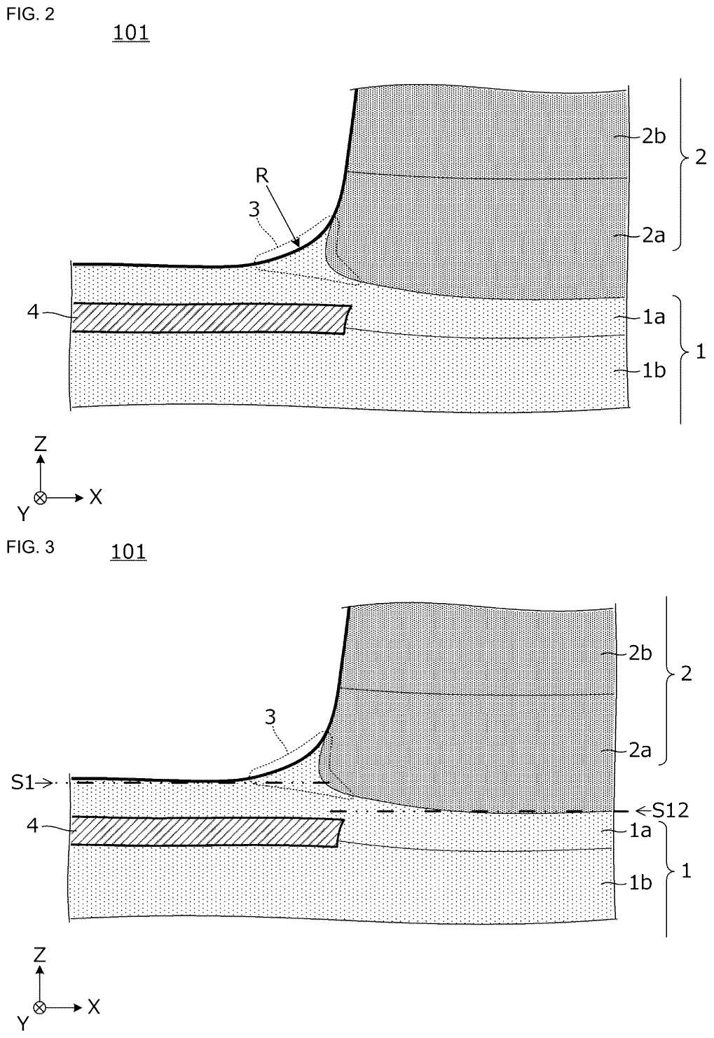

FIG. 2 is a diagram illustrating, in particular, the shape of the raised portion 3. FIG. 2 is, similarly to the lower diagram in FIG. 1, an enlarged view of the VP region in the upper diagram in FIG. 1. The outer surface of the raised portion 3 is curved so as to form a gentle continuous surface from an upper surface of the first board portion 1 to a side surface of the second board portion 2. Arrow R in FIG. 2 indicates the gentle curved surface.

As mentioned before, in general, assuming an external force is exerted on a multilayer board so as to curve the multilayer board, stress is more likely to concentrate at portions where the number of laminated resin layers increases. Since the periphery of the joint surface between the first board portion 1 and the second board portion 2 is a gentle continuous curved surface in the multilayer board 101 of the present embodiment, the stress exerted on the portion where the number of laminated resin layers increases is relieved. This prevents cracks and chips at the interface between the first board portion 1 and the second board portion 2, reducing the deformation of the second board portion 2 such as inclination because the second board portion 2 has a higher rigidity than the first board portion 1.

FIG. 3 is a diagram illustrating the positional relationship between the first board portion 1 and the second board portion 2. In FIG. 3, S12 indicates the bottom portion of the second board portion 2 which is part of the joint surface of the second board portion 2 with the first board portion 1, and S1 indicates the upper surface of the first board portion 1. Both of them are represented by planes parallel to the X-Y plane in FIG. 3.

As illustrated in FIG. 3, the bottom portion S12 of the second board portion 2 is located below the upper surface S1 of the first board portion 1 in the Z-axis direction. With this structure, the first material of the first board portion 1 is more likely to be raised around the base portion 2B of the second board portion 2, and thus the raised portion 3 is raised greatly. This easily increases the joining strength between the first board portion 1 and the second board portion 2.

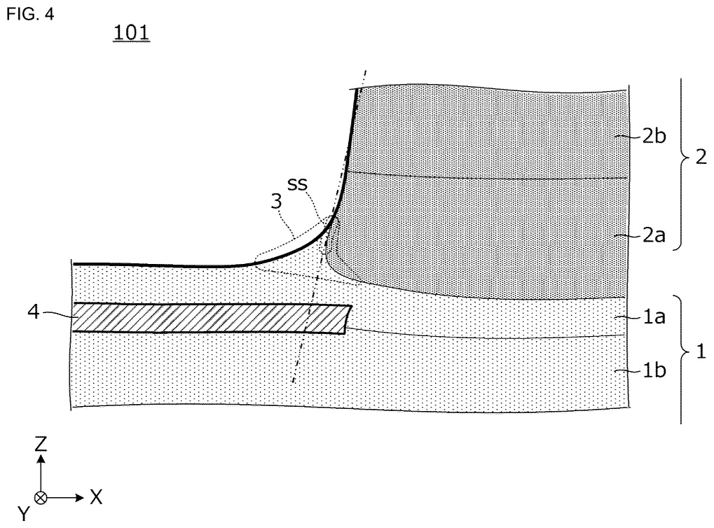

FIG. 4 is a diagram illustrating the shape of the joint portion between the first board portion 1 and the base portion 2B of the second board portion 2. The boundary between the raised portion 3 and the side portion 2S of the second board portion 2 has an inclined portion SS extending downward from the top of the raised portion 3 such that the width of the side portion 2S of the second board portion 2 increases. The dashed double-dotted line in FIG. 4 indicates the inclination angle of the inclined portion SS.

As described above, the inclined portion SS is inclined relative to the Z-axis direction at such an angle that the width of the side portion 2S of the second board portion 2 increases from the top of the raised portion 3 to the bottom. With this structure, the amount of the first material of the first board portion 1 for covering the portion around the base portion 2B of the second board portion 2 is more likely to increase. This easily increases the joining strength between the first board portion 1 and the second board portion 2.

As mentioned earlier, in general, assuming a multilayer board is curved, stress is more likely to concentrate at portions where the number of laminated resin layers increases. In the multilayer board 101 of the present embodiment, the holding force is high for holding the second board portion 2 with the first material in the direction of the main part of the first board portion 1. Thus, cracks and chips are prevented at the interface between the first board portion 1 and the second board portion 2.

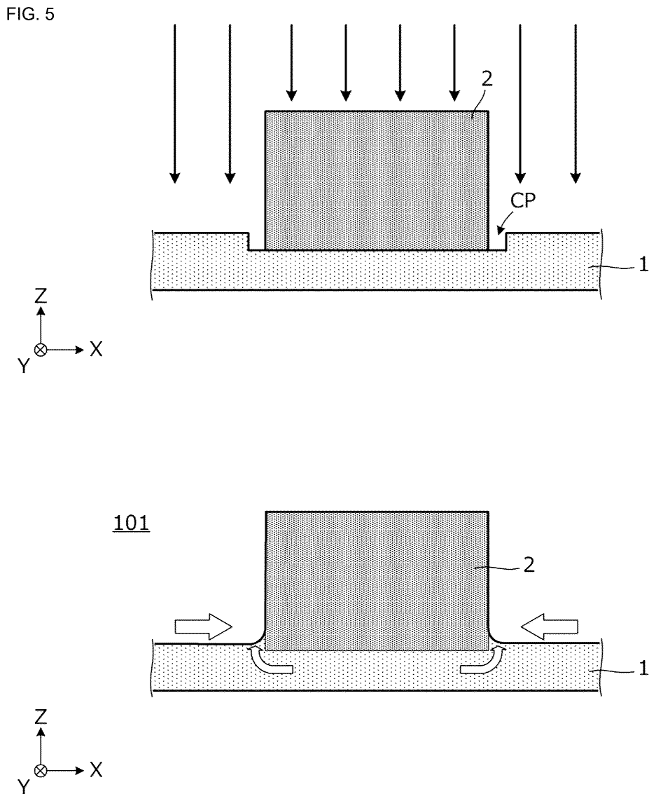

FIG. 5 includes sectional views of the multilayer board 101 during manufacturing. An upper diagram in FIG. 5 illustrates the second board portion 2 laminated on the first board portion 1 being thermal-pressure bonded to the first board portion 1 by, for example, isostatic pressing during manufacturing of the multilayer board 101. In this stage, the first board portion 1 is a laminated board including a plurality of resin layers and conductor layers and has a recess CP at a specified position in an upper portion. The second board portion 2 is an individual piece of a laminated board including a plurality of resin layers and conductor layers.

The recess CP of the first board portion 1 is a region where the second board portion 2 is mounted. When viewed in the Z-axis direction, the area of the recess CP of the first board portion 1 is slightly larger than the area of the joint portion between the first board portion 1 and the second board portion 2.

Downward arrows in the upper diagram in FIG. 5 represent heating and pressing. In the case in which the first board portion 1 is composed of a thermoplastic resin, such thermal pressure bonding causes the first material to flow to the recess CP of the first board portion 1 where the second board portion 2 is mounted, so that the second board portion 2 is partially buried in the first board portion 1.

Arrows in a lower diagram in FIG. 5 represent resin flows of the first material of the first board portion 1. A resin layer of the first board portion 1 is raised relative to the second board portion 2, and upper portions of the first board portion 1 are pressed in directions parallel to the X-Y plane toward side surfaces of the second board portion 2. This forms the structure including the first board portion 1, the second board portion 2, and the raised portion 3 illustrated in FIGS. 1 to 4.

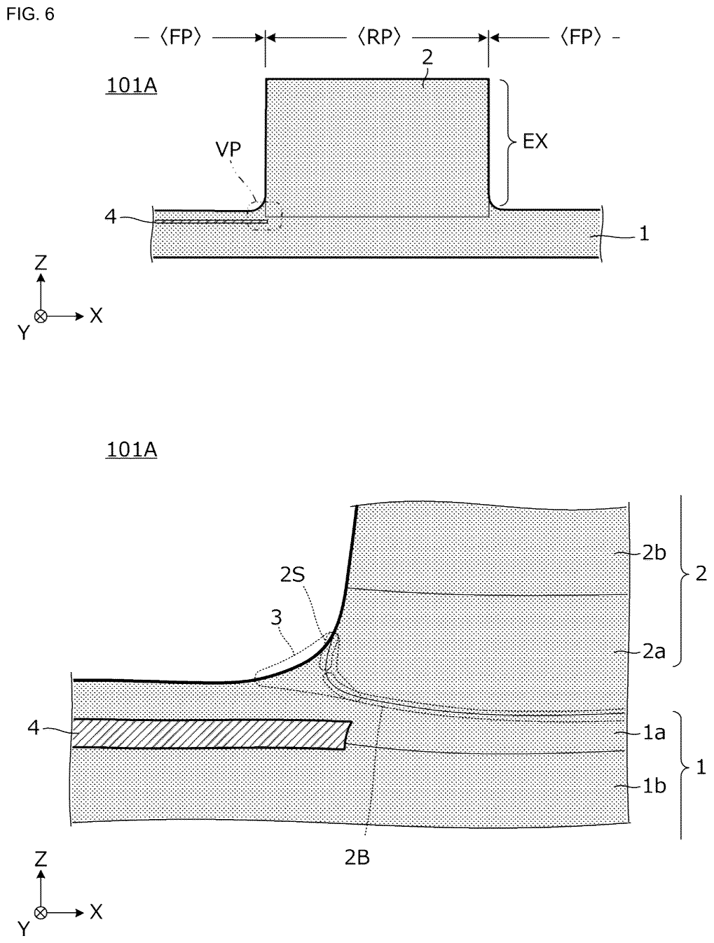

FIG. 6 includes sectional views of another multilayer board 101A according to the first embodiment. In FIG. 6, an upper diagram illustrates a sectional view of part of the multilayer board 101A, and a lower diagram illustrates an enlarged view of a VP region in the upper diagram.

In the example illustrated in FIGS. 1 to 5, both the first material composing the first board portion 1 and the second material composing the second board portion 2 are, for example, liquid crystal polymer resins (LCPs) but do not have the same composition. In contrast, in the multilayer board 101A illustrated in FIG. 6, the first material composing the first board portion and the second material composing the second board portion 2 are the same. For example, both are composed of liquid crystal polymer resins (LCPs) having the same composition.

Instead of liquid crystal polymer resins (LCPs), polyimide or the like which is used for flexible boards may be used. For example, the first material composing the first board portion 1 may be a liquid crystal polymer resin (LCP) which is highly flexible, and the second material composing the second board portion 2 may be, for example, an epoxy board or the like containing glass base material which is highly rigid and used for printed boards.

In the case in which the second material of the second board portion 2 and the first material of the first board portion are the same, the adhesion strength between the first board portion 1 and the second board portion 2 is high.

### Second Embodiment

The second embodiment describes, as an example, a multilayer board 102 in which internal and surface configurations are illustrated.

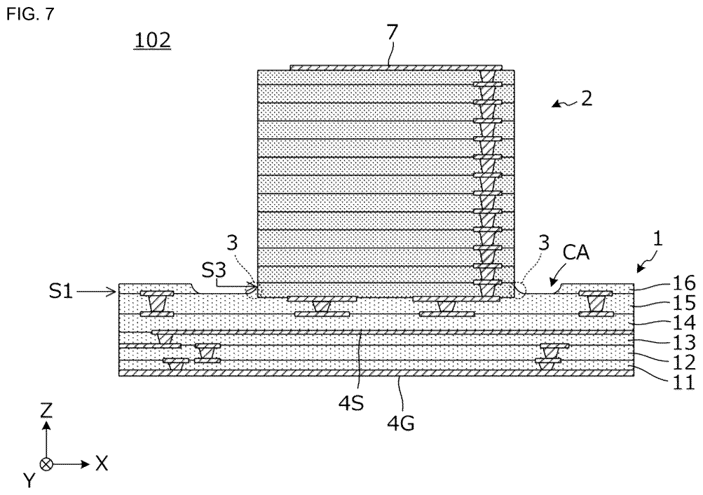

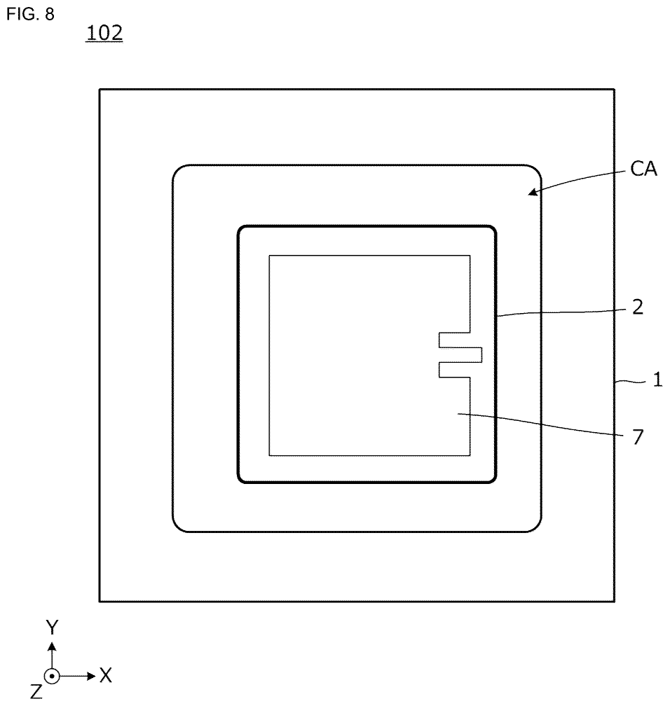

FIG. 7 is a sectional view of the multilayer board 102 according to the second embodiment. FIG. 8 is a plan view of the multilayer board 102. In this example, a first board portion 1 having a rectangular planar shape has a cavity CA having a rectangular planar shape, in which a second board portion 2 is formed.

The first board portion 1 includes a plurality of resin layers 11, 12, 13, 14, 15, and 16, Cu foils each attached to one side of the respective resin layers 11, 12, 13, 14, 15, and 16, and interlayer connection conductors formed inside the resin layers 11, 12, 13, 15, and 16. These interlayer connection conductors are composed of Cu or Ag, which is, for example, formed by plating in either case.

In this example, the resin layers 11, 12, 13, 14, 15, and 16 are composed of, for example, thermoplastic resins such as liquid crystal polymer resins (LCPs) and laminated by the joint between the resin layers adjoining one another in the lamination direction and the joint between each resin layer and the corresponding Cu foil adjoining each other in the lamination direction.

Inside the first board portion 1, a pattern of signal lines is formed in a conductor layer 4S composed of a Cu foil, and a ground conductor layer is formed in a conductor layer 4G composed of a Cu foil. These conductor layers 4S and 4G and the resin layers 11, 12, and 13 between them compose a microstrip transmission line. The transmission line formed in the first board portion 1 as described above enables a rigid-flexible board in which a circuit connected to the second board portion 2 and the aforementioned transmission line are integrated, achieving space saving as a whole.

The resin layer 16 has an opening, and the opening and the lamination of the resin layers 11, 12, 13, 14, 15, and 16 and the Cu foils form the cavity CA in part of a surface of the multilayer body.

At the interface between a bottom surface of the cavity CA and a bottom surface of the second board portion 2, a raised portion 3 is formed around the bottom surface of the second board portion 2. The height of the raised portion 3 in the Z direction is less than the depth of the cavity CA.

Although the recess CP illustrated in the upper diagram in FIG. 5 is a region where the second board portion 2 is mounted and is a recess formed in the first board portion 1 and slightly larger than the outer shape of the second board portion 2, the cavity CA illustrated in FIG. 7 is a recess formed in the first board portion 1 and larger than the outer shape of the second board portion 2.

Since the second board portion 2 is laminated in the cavity CA of the first board portion 1 as described above, the height of the raised portion 3 is less than the depth of the cavity CA. This prevents the rising of the raised portion 3 from adversely affecting other members. For example, even assuming another member is located on the upper surface of the first board portion 1, the member is not in contact with the raised portion 3 and the structure as a whole is maintained to be small-sized.

As illustrated in FIG. 8, the second board portion 2 has a radiating electrode 7 on an upper surface thereof, and the radiating electrode 7 functions as a patch antenna, together with the ground conductor layer formed near a lower surface of the second board portion 2 or a Cu foil of the first board portion 1 used as the ground conductor layer.

The second material which is the material of the second board portion 2 has a higher permittivity than the first material which is the material of the first board portion. Thus, the high permittivity of the second board portion can be effectively utilized. For example, the patch antenna can be reduced in size in the present embodiment. In addition, the ratio of the rigid portion in the multilayer board can be reduced.

Since the second board portion 2 has a higher rigidity than the first board portion 1 in the present embodiment, the deformation such as inclination of the second board portion 2 can be reduced. This reduces the deviation in the radiation direction (directivity) of the antenna.

### Third Embodiment

The third embodiment describes, as an example, a multilayer board in which a first board portion includes a bent portion.

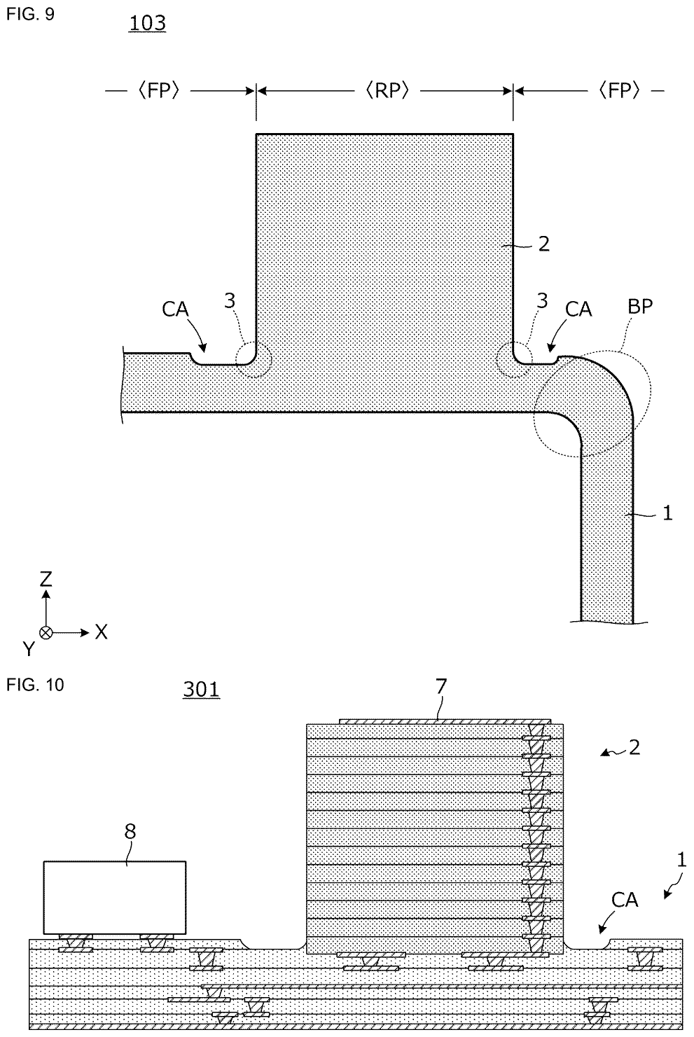

FIG. 9 is a sectional view of a multilayer board 103 according to the third embodiment. The multilayer board 103 has a configuration the same as or similar to that of the multilayer board 102 illustrated in FIG. 7. Since the first board portion 1 has flexibility, the first board portion 1 can be bent at an intended position.

In the example illustrated in FIG. 9, the first board portion 1 is bent at 90° with a specified curvature at a bent portion BP. Even though the first board portion 1 is bent as mentioned above, the presence of the raised portion 3 reduces the stress generated around the interface between the first board portion 1 and the second board portion 2.

Since the deformation of the rigid portion RP is small assuming the flexible portion FP is bent, the characteristics of the electronic-component-like function formed on the rigid portion RP can be kept stable.

### Fourth Embodiment

The fourth embodiment illustrates an electronic device according to the present disclosure as an example.

FIG. 10 is a sectional view of an electronic device 301 according to the fourth embodiment. The electronic device according to the present disclosure includes a multilayer board according to the present disclosure and an electronic component mounted on the multilayer board.

In the example illustrated in FIG. 10, an electronic component 8 is mounted on the first board portion 1. The electronic component 8 is, for example, a chip capacitor for impedance matching for a signal transmission line connected to the radiating electrode 7, a power amplification IC configured to output transmission signals to the radiating electrode 7, a signal amplification IC configured to amplify signals received by the radiating electrode 7, or the like.

Although various embodiments according to the present disclosure have been presented as above, all of these are examples, and these presentations are not intended to limit the scope of the present disclosure. The embodiments according to the present disclosure can be omitted, replaced, or changed in various manners within a scope not departing from the spirit of the disclosure. The embodiments including such various kinds of omission, replacement, or change are included in the scope of the present disclosure and the spirit of the present disclosure and also included in the disclosure defined in the claims of the present application and the equivalents thereof.

For example, although the second embodiment and the fourth embodiment describe examples in which a patch antenna is formed on the second board portion 2, the present disclosure can be applied to multilayer boards in which another circuit is formed on the second board portion 2.

The multilayer boards and electronic devices of the present disclosure may be provided in the aspects described below.

<1>

A multilayer board including:
a first board portion that includes laminated resin layers each composed of a first material;
a second board portion that includes laminated resin layers each composed of a second material, is joined to the first board portion, and includes a protruding portion protruding from the first board portion; and
a raised portion composed of the first material, joined to a base portion of the protruding portion of the second board portion, raised around the base portion of the protruding portion, and covering part of a side portion of the protruding portion, in which
a bottom portion of the second board portion, the bottom portion being part of a joint surface of the second board portion with the first board portion, is located below an upper surface of the first board portion.
   <2>

The multilayer board according to <1>, in which
a boundary between the raised portion and a side portion of the second board portion includes an inclined portion extending downward from a top of the raised portion such that the width of the side portion of the second board portion increases.

Further embodiments follow.

<3>

The multilayer board according to <1> or <2>, in which
the first material and the second material are the same material.

Further embodiments follow.

<4>

The multilayer board according to any one of <1> to <3>, in which
the second material has a higher permittivity than the first material.

Further embodiments follow.

<5>

The multilayer board according to any one of <1> to <4>, in which
the first material and the second material are thermoplastic resins.
   <6>

The multilayer board according to <5>, in which
the thermoplastic resins are liquid crystal polymer resins.
   <7>

The multilayer board according to any one of <1> to <6>, in which
the first material has a lower Young's modulus than the second material.

Further embodiments follow.

<8>

The multilayer board according to any one of <1> to <7>, in which
the first board portion has a cavity recessed from the upper surface of the first board portion,
the second board portion is joined to a bottom portion of the cavity of the first board portion,
the raised portion is located in the cavity, and
part of the second board portion protrudes beyond the upper surface of the first board portion.
   <9>

The multilayer board according to any one of <1> to <8>, in which
the second board portion includes an antenna.
   <10>

The multilayer board according to any one of <1> to <9>, in which
the first board portion includes a transmission line.
   <11>

The multilayer board according to any one of <1> to <10>, in which
the first board portion includes a bent portion.
   <12>

An electronic device including:
the multilayer board according to any one of <1> to <11>; and
an electronic component mounted on the multilayer board.

What is claimed is:

1. A multilayer board comprising:
a first board portion that includes laminated resin layers each composed of a first material;
a second board portion that includes laminated resin layers each composed of a second material, is joined to the first board portion, and includes a protruding portion protruding from the first board portion; and
a raised portion composed of the first material, joined to a base portion of the protruding portion of the second board portion, raised around the base portion of the protruding portion, and covering part of a side portion of the protruding portion, wherein
a bottom portion of the second board portion, the bottom portion being part of a joint surface of the second board portion with the first board portion, is located below an upper surface of the first board portion.

2. The multilayer board according to claim 1, wherein
a boundary between the raised portion and a side portion of the second board portion includes an inclined portion extending downward from a top of the raised portion such that the width of the side portion of the second board portion increases.

3. The multilayer board according to claim 1, wherein
the first material and the second material are the same material.

4. The multilayer board according to claim 1, wherein
the second material has a higher permittivity than the first material.

5. The multilayer board according to claim 1, wherein
the first material and the second material are thermoplastic resins.

6. The multilayer board according to claim 5, wherein
the thermoplastic resins are liquid crystal polymer resins.

7. The multilayer board according to claim 1, wherein
the first material has a lower Young's modulus than the second material.

8. The multilayer board according to claim 1, wherein
the first board portion has a cavity recessed from the upper surface of the first board portion,
the second board portion is joined to a bottom portion of the cavity of the first board portion,
the raised portion is located in the cavity, and
part of the second board portion protrudes beyond the upper surface of the first board portion.

9. The multilayer board according to claim 1, wherein
the second board portion includes an antenna.

10. The multilayer board according to claim 1, wherein
the first board portion includes a transmission line.

11. The multilayer board according to claim 1, wherein
the first board portion includes a bent portion.

12. An electronic device comprising:
the multilayer board according to claim 1; and
an electronic component mounted on the multilayer board.

13. The multilayer board according to claim 2, wherein
the first material and the second material are the same material.

14. The multilayer board according to claim 2, wherein
the second material has a higher permittivity than the first material.

15. The multilayer board according to claim 2, wherein
the first material and the second material are thermoplastic resins.

16. The multilayer board according to claim 15, wherein
the thermoplastic resins are liquid crystal polymer resins.

17. The multilayer board according to claim 2, wherein
the first material has a lower Young's modulus than the second material.

18. The multilayer board according to claim 2, wherein
the first board portion has a cavity recessed from the upper surface of the first board portion,
the second board portion is joined to a bottom portion of the cavity of the first board portion,
the raised portion is located in the cavity, and
part of the second board portion protrudes beyond the upper surface of the first board portion.

19. The multilayer board according to claim 2, wherein
the second board portion includes an antenna.

20. The multilayer board according to claim 2, wherein
the first board portion includes a transmission line.
